(19) United States
(12) Patent Application Publication
(10) Pub. No.: US 2013/0155629 A1
(43) Pub. Date: Jun. 20, 2013

(54) Hermetic Semiconductor Package Structure and Method for Manufacturing the same

(71) Applicant: Shao-Pin Ru, New Taipei City (TW)

(72) Inventor: Shao-Pin Ru, New Taipei City (TW)

(73) Assignee: TONG HSING ELECTRONIC INDUSTRIES, LTD., Taipei City (TW)

(21) Appl. No.: 13/469,052

(22) Filed: May 10, 2012

Related U.S. Application Data
(60) Provisional application No. 61/577,094, filed on Dec. 19, 2011.

(51) Int. Cl. H05K 7/00; H05K 3/30

(52) U.S. Cl. 361/746; 361/728; 29/832

(57) ABSTRACT

The invention provides a semiconductor package structure, comprising: a substrate having a first surface and a second surface; a first conductive layer plated on the first surface; a semiconductor element attached to the first conductive layer on the first surface of the substrate for electrically connecting; a second conductive layer plated on the first surface and surrounded the semiconductor element and the first conductive layer, wherein the height of the second conductive layer is higher than the first conductive layer; and a lid attached to the top of the second conductive layer for sealing the semiconductor element.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

This invention relates to a package structure, and more particularly, to a semiconductor package structure for controlling the package scale, line width and line pitch with great precision.

2. Description of Related Arts

The microelectronics industry is constantly striving for further miniaturization of components to increase speed and functionality for a given system. This has led to the development of the so-called very large scale integration (VLSI) of a number of electronic components such as integrated circuit chips, individual components and fiber optic coupling devices into a single integrated package. Ceramic substrate technology in the electronic business is always considered in the sense of “ceramic printed boards” or more precisely as film integrated circuits. Ceramic substrates are widely used in the field of microelectronic packaging, especially for the specific devices like crystals, oscillators, saw filters, MEMS devices or any other sensitive ICs that require strong conditions for having an air cavity inside, high reliability, and hermeticity properties. For example, in crystal devices, the frequency shift is always the major issue, and is strongly dependant on the environment temperature, humidity, and atmosphere. Therefore, the quartz has to be put into an isolated environment, in order to maintain the stable crystal characteristic. Ceramic just has solid property to make an air cavity for protection. As the reason, HTCC package becomes current technology of packaging the most of crystal devices.

Advantages of HTCC includes mechanical rigidity and hermeticity, both of which are important in high-reliability and environmentally stressful applications. LTCC also features the ability to embed semiconductor elements into the ceramic package minimizing the size of the completed module. However, no matter HTCC or LTCC, problems of shrinkage and imprecision controlling of package scale, conductor thickness, line width and line pitch always occur due to cofired process (1600° C. for HTCC and 850° C. for LTCC), therefore, they are difficult to shape in small scale packages. In addition, due to the printed process for these two technologies, the uniformity of metal is not good and the minimum line width and spacing (L/S) can not be too small (4 mils). Also, the ceramic substrate is very easy to get warped during firing, and is difficult to make compact packages.

Direct Plated Copper (DPC) process on ceramic substrate is basically combined two technologies, thin film process and electrolytic plating process, to form the metallization by photolithography on fired ceramic substrate, and is a well mature process that has been utilized as an outstanding solution for high power, high heat-dissipation, and high reliability applications. DPC process starts from sputtering thin metal layers on ceramic substrates as the seed layer for plating. Then photolithographic procedures are utilized to develop the circuit pattern. Then Copper (Cu) is plated on top of seed layers to form a solid structure for circuitry, and is covered with a surface finish layer (Ni/Au, Ni/Pd/Au, Ag, or Ni/Ag, etc) to prevent the copper oxidation. All the DPC processes are done on fired ceramics without high temperature firing process like HTCC or LTCC, so no shrinkage and warpage problems will be happened in DPC substrates.

DPC substrates offer several key attributes such as good Coefficient of Thermal Expansion (CTE) match to semiconductor materials like Si-based or III-V-based semiconductor dice, high thermal conductivity, low electrical resistance conductor traces (with Cu conductor), good reliable at high temperatures (>340° C.), precise features, and ease of large format assembly. In additions, by using the photolithography, this ceramic solution achieves fine line resolution allowing high density of devices and circuitry (done to 2 mils for min L/S), proven reliability, mechanically rugged ceramic construction, and reasonable cost. DPC process can also work on various types of ceramic or semiconductor materials, like aluminum nitride (AlN), alumina (Al2O3), zirconium toughened alumina (ZTA), silicon (Si), silicon nitride (Si3N4), or beryllium oxide (BeO), etc.

The plated circuitry formed by DPC provides very fine feature and controllable Cu thickness, the thickness range can be from very thin (1 um) to very think (300 um) for various requirements and applications. Therefore, for some specific packages that need air cavity structure for hermeticity requirement, the DPC substrate can also generate the cavity structure by electrolytic plating easily. In DPC substrate, the plated Cu with thinner thickness can be used as circuitry for electrical and thermal interconnections. However, for another plated Cu with thicker thickness that surrounds the thinner plated Cu, which can be considered as a Cu wall to form the cavity structure.

In DPC substrates with such air cavity structure, the cavity size and thickness of quartz pad are arbitrary to change for different application. Besides, the uniform and accurate pattern can improve the process yield in quartz assembly. And AuSn layer can be also plated on the Cu wall of DPC substrates, for sealing the Kovar lid on the DPC bases. However, due to the good uniformity of ceramic and plated metal, the AuSn layer does not need that thick to cover the warpage, normally, 5 um AuSn thickness is enough for sealing the lid to save the cost.

Referring to FIG. 19, Taiwan. Pat. No. 368184, the contents of which are hereby incorporated by reference, discloses a hermetic chip package structure. The structure comprises a ceramic substrate, a metal frame and a metal lid. The metal frame and the ceramic substrate are connected by high temperature soldering. Although the structure provides good hermiticity, however, problems of imprecise dimensional control and difficult to shape in small scale packages are also remained.

Referring to FIG. 20, Taiwan. Pat. No. 331378, the contents of which are hereby incorporated by reference, discloses a MEMS hermetic package structure. The structure comprises a ceramic substrate, a dam and a metal lid. The dam and the ceramic substrate are connected by adhesive. Although the structure provides a good hermetic seal, however, problems of imprecision and difficult to shape in small scale packages are also remained.

Referring to FIG. 21, Taiwan. Pat. No. 1256709, the contents of which are hereby incorporated by reference, discloses a semiconductor device package. The structure comprises a ceramic substrate, a wall and a metal lid. Although the wall is disposed on the ceramic substrate, however, Taiwan. Pat. No. 1256709 does not disclose how to combine the wall and the ceramic substrate.

It is desirable, therefore, to provide a semiconductor structure with great precision and for solving problems aforementioned.

### SUMMARY OF THE PRESENT INVENTION

An object of the present invention is to provide a semiconductor package structure for controlling the package scale, line widths and line pitches with great precision.

To achieve the abovementioned object, the invention provides a semiconductor package structure, comprising:

a substrate having a first surface and a second surface and a metal contact penetrating the substrate from the first surface to the second surface;

a first conductive layer plated on the first surface of the substrate and connecting to the metal contact;

a semiconductor element electrically connecting the first conductive layer on the first surface of the substrate;

a second conductive layer plated on the first surface of the substrate and surrounding the first conductive layer and the semiconductor element, wherein the height of the second conductive layer is higher than the first conductive layer; and

a lid attached to the top of the second conductive layer for sealing the semiconductor element.

According to the semiconductor package structure aforementioned, the substrate is a ceramic substrate.

According to the semiconductor package structure aforementioned, it further comprises a surface finish layer which is plated on the surface of the first and second conductive layer.

According to the semiconductor package structure aforementioned, it further comprises a third conductive layer between the first surface of the substrate and the second conductive layer, wherein the third conductive layer surrounds the first conductive layer.

According to the semiconductor package structure aforementioned, it further comprises a surface finish layer plated on the surface of the first conductive layer and second conductive layer and third conductive layer.

According to the semiconductor package structure aforementioned, the lid is formed by pure metal, metal alloy, metal composite which could be a combination of metals or metal with ceramic additives, plastic or ceramic materials.

According to the semiconductor package structure aforementioned, the semiconductor element and the first conductive layer are electrically connected by wire, wherein the materials of the wire comprise any conductive material including, but not limited to Au, Al, Cu, Ag.

According to the semiconductor package structure aforementioned, the semiconductor element and the first conductive layer are electrically connected by bumps, wherein the materials of the bumps comprise any conductive material including, but not limited to solder, sliver paste, Au, Cu.

According to the semiconductor package structure aforementioned, it further comprises a redistribution layer plated on the second surface of the substrate and electrically connecting to the metal contact, wherein the redistribution layer is plated by the surface finish layer.

According to the semiconductor package structure aforementioned, the surface finish layer is for antirust, and formed by conventional method.

According to the semiconductor package structure aforementioned, the surface finish layer is selected from the group consisting of Ag, Au, Ni, Pd and a combination of those, but not limited.

According to the semiconductor package structure aforementioned, the ceramic substrate is a multi-layer ceramic.

Another embodiment of the invention provides a method for manufacturing semiconductor package structure, comprising the steps of

(a) providing a substrate having a first surface and a second surface and a opening penetrating the substrate from the first surface to the second surface;

(b) forming a metal contact in the opening;

(c) plating a first conductive layer on the first surface of the substrate, wherein the first conductive layer is electrically connected to the metal contact;

(d) plating a second conductive layer on the first surface of the substrate for surrounding the semiconductor element and the first conductive layer, wherein the height of the second conductive layer is higher than the first conductive layer;

(e) attaching a semiconductor element to the first conductive layer on the first surface of the substrate for electrically connecting; and

(f) attaching a lid to the top of the second conductive layer for sealing the semiconductor element.

According to the method for manufacturing semiconductor package structure aforementioned, between the step (d) and (e), the method further comprises a step of plating a surface finish layer on the surfaces of the first and second conductive layer, wherein the surface finish layer is selected from the group consisting of Ag, Au, Ni, Pd, and a combination of those, but not limited.

According to the method for manufacturing semiconductor package structure aforementioned, the surface finish layer is formed by electrochemical deposition.

According to the method for manufacturing semiconductor package structure aforementioned, the semiconductor element connects to the first conductive layer electrically by wire bonding.

According to the method for manufacturing semiconductor package structure aforementioned, the semiconductor element connects to the first conductive layer electrically by flip chip bonding.

According to the method for manufacturing semiconductor package structure aforementioned, the step (c) further comprises a step of plating a third conductive layer between the first surface of the substrate and the second conductive layer, wherein the third conductive layer surrounds the first conductive layer.

According to the method for manufacturing semiconductor package structure aforementioned, it further comprises the step of plating a redistribution layer on the second surface of the substrate for electrically connecting to the metal contact.

According to the method for manufacturing semiconductor package structure aforementioned, after the step (b), the method further comprises a step of plating a redistribution layer on the second surface of the substrate for electrically connecting to the metal contact.

According to the method for manufacturing semiconductor package structure aforementioned, the step (b) and the step (c) simultaneously take place.

According to the method for manufacturing semiconductor package structure aforementioned, the steps of plating the metal contact and the first conductive layer and the redistribution layer take place simultaneously.

According to the method for manufacturing semiconductor package structure aforementioned, the steps of plating the metal contact and the first conductive layer and the redistribution layer and the third conductive layer take place simultaneously.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

The details and technology of the present invention are described below with reference to the accompanying drawings.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 is a cross section view of the semiconductor package structure of the present invention in the first manufacturing process.

FIG. 2 is a cross section view of the package structure of the present invention in the manufacturing process after FIG. 1.

FIG. 3 is a cross section view of the package structure of the present invention in the manufacturing process after FIG. 2.

FIG. 4 is a cross section view of the package structure of the present invention in the manufacturing process after FIG. 3.

FIG. 5 is a cross section view of the package structure of the present invention in the manufacturing process after FIG. 4.

FIG. 6 is a cross section view of the package structure of the present invention in the manufacturing process after FIG. 5.

FIG. 7 is a cross section view of the package structure of the present invention in the manufacturing process after FIG. 6.

FIG. 8 is a cross section view of the package structure of the present invention in the manufacturing process after FIG. 7.

FIG. 9 is a cross section view of the package structure of the present invention in the manufacturing process after FIG. 8.

FIG. 10 is a cross section view of the semiconductor package structure of the present invention in the second manufacturing process.

FIG. 11 is a cross section view of the package structure of the present invention in the manufacturing process after FIG. 10.

FIG. 12 is a cross section view of the package structure of the present invention in the manufacturing process after FIG. 11.

FIG. 13 is a cross section view of the package structure of the present invention in the manufacturing process after FIG. 12.

FIG. 14 is a cross section view of the package structure of the present invention in the manufacturing process after FIG. 13.

FIG. 15 is a cross section view of the package structure of the present invention in the manufacturing process after FIG. 14.

FIG. 16 is a cross section view of the package structure of the present invention in the manufacturing process after FIG. 15.

FIG. 17 is a cross section view of the package structure of the present invention in the manufacturing process after FIG. 15.

FIG. 18 is a cross section view of the package structure of the present invention in the manufacturing process after FIG. 17.

FIGS. 19˜21 are sectional views according to the conventional package structure.

### DETAILED DESCRIPTION OF THE PREFERRED EMBODIMENT

For clarity of disclosure, and not by way of limitation, the detailed description of the invention is divided into the subsections that follow.

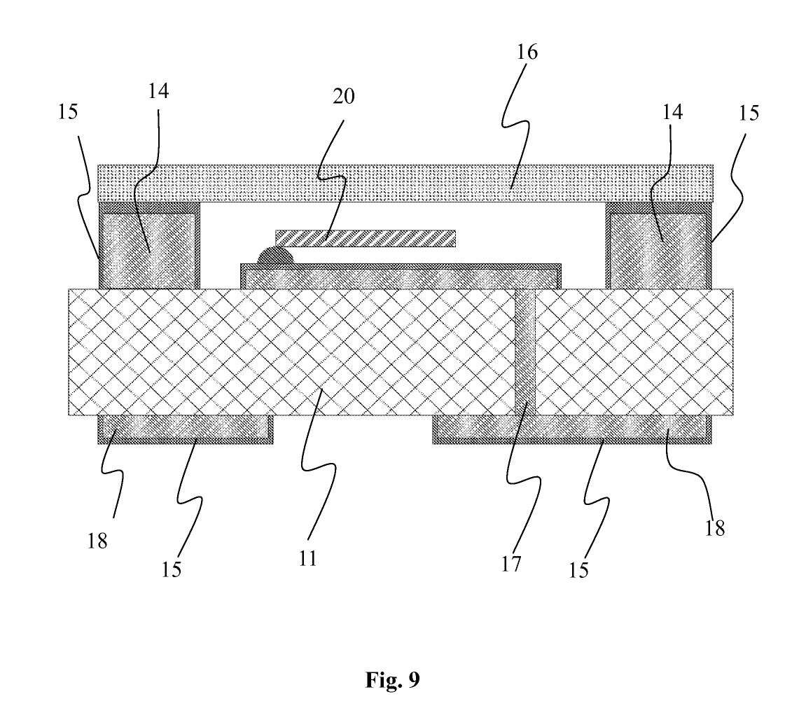

With reference to FIG. 9, this illustrates a cross section view of the semiconductor package structure of the present invention. The semiconductor package structure 10 comprises a substrate 11 having a first surface and a second surface, a first conductive layer 12, a second conductive layer 14, a surface finish layer 15, a semiconductor element 20, and a lid 16. The substrate 11 is a ceramic substrate. The first conductive layer 12 and the second conductive layer 14 are both plated on the first surface of the substrate 11, and the semiconductor element 20 electrically connects the first conductive layer 12 on the first surface of the substrate. The second conductive layer 14 surrounds the semiconductor element 20 and the first conductive layer 12. The surface finish layer 15 is formed on the surfaces of the first conductive layer 12 and the second conductive layer 14 for protecting the first conductive layer 12 and the second conductive layer 14. The lid 16 is attached to the top of the second conductive layer 14 for sealing the semiconductor element.

The direct plated copper (DPC) process on metalized ceramic substrate is originally created to replace the direct bonded copper (DBC) process because of its better electrical, thermal and mechanical performance. DPC also has a good ability in thickness control for the copper layer, from very thin to very thick. For fine pitch design, a minimum conductor line width/spacing of 3 mils can be easily obtained, and via holes are filled with copper for good electrical and thermal characteristics. Therefore, the first conductive layer 12 and the second conductive layer 14 of the present invention formed by DPC have good ability rather than HTCC and LTCC for controlling the package scale, line widths and line pitches with great precision.

In FIG. 9, the substrate 11 further comprises a metal contact 17 penetrating the substrate from the first surface to the second surface for electrically connecting to the first conductive layer 12. The surface finish layer 15 is formed on the surfaces of the first conductive layer 12 and the second conductive layer 14 by electrochemical deposition. The lid 16 is formed by ceramic materials. The semiconductor element 20 and the first conductive layer 12 are electrically connected by flip chip bonding. Moreover, the semiconductor package structure 10 further comprises a redistribution layer 18 plated on the second surface of the substrate 11 for electrically connecting to the metal contact 17, wherein the surface finish layer 15 is plated on the surface of the redistribution layer 18 for protecting. The surface finish layer 15 for protecting the first conductive layer 12 and the second conductive layer 14 and the redistribution layer 18 is consisted of gold and nickel. Therefore, the semiconductor element 20 is electrically conducting to peripheral circuits through the first conductive layer 12, the metal contact 17 and the redistribution layer 18.

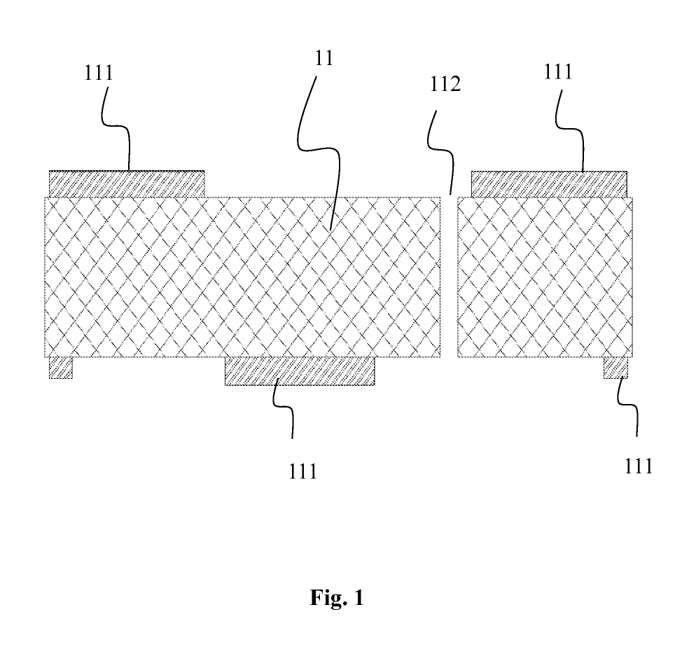

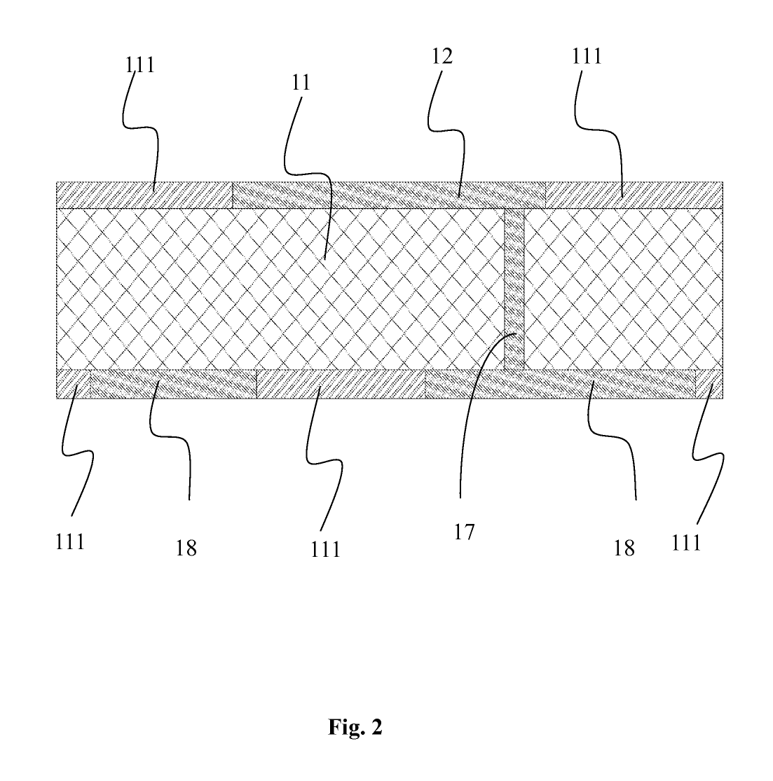

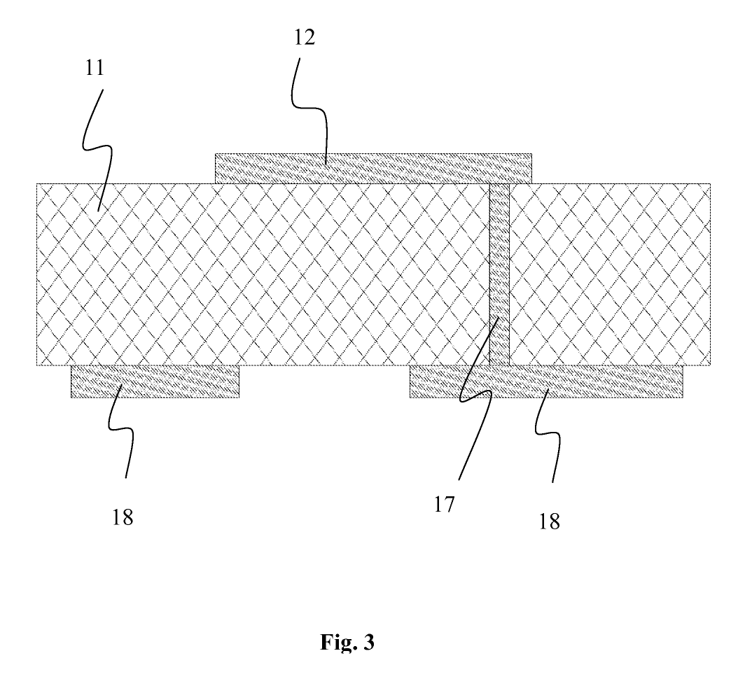

Referencing to FIGS. 1 to 9, the method of manufacturing the semiconductor package structure of the present invention is illustrated. As shown in FIG. 1, a substrate 11 having a first surface and a second surface is provided at first. An opening 112 extending from the first surface to the second surface of the substrate 11 is formed by laser drilling. Due to plating conductive layers on particular position of the substrate 11, photo-resistors 111 should be patterned on the first surface and the second surface of the substrate 11 for defining the position of the first conductive layer 12 and the redistribution layer 18 (shown in FIG. 2). Moreover, the substrate 11 is a ceramic substrate.

With reference to FIG. 2, this illustrates a cross section of the package structure of the present invention in the manufacturing process after FIG. 1. As shown, a metal contact 17 is formed in the opening 112 extending from the first surface and the second surface of the substrate 1. A first conductive layer 12 is plated on the first surface of the substrate 11 by DPC. A redistribution layer 18 is plated on the second surface of the substrate 11 by DPC. Besides, the first conductive layer 12, the metal contact 17 and the redistribution layer 18 are electrically connected.

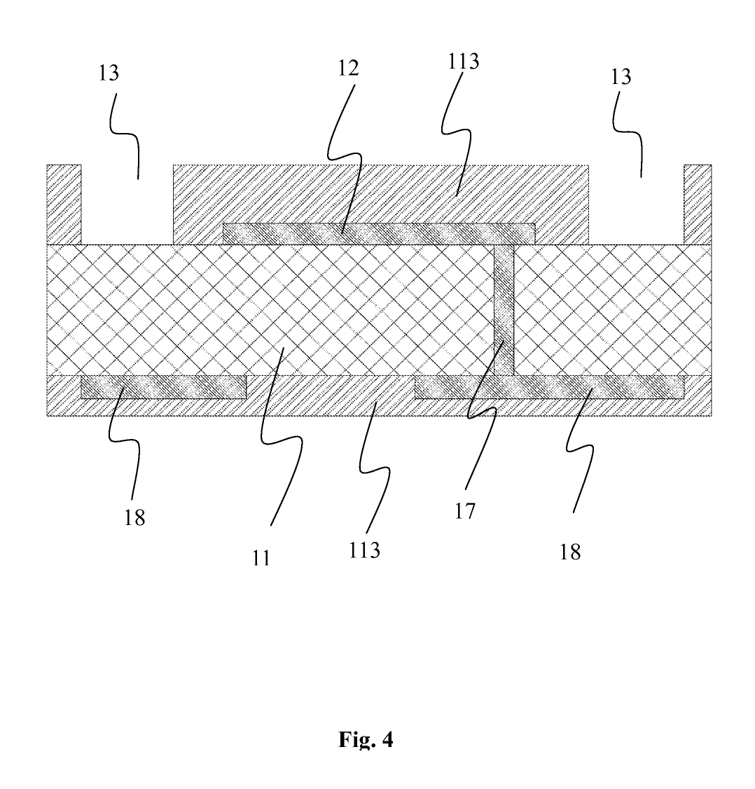

With reference to FIG. 3, this illustrates a cross section of the package structure of the present invention in the manufacturing process after FIG. 4. As shown, after the redistribution layer 18 and the first conductive layer 12 are formed, the photo-resistors 111 are stripped by etching.

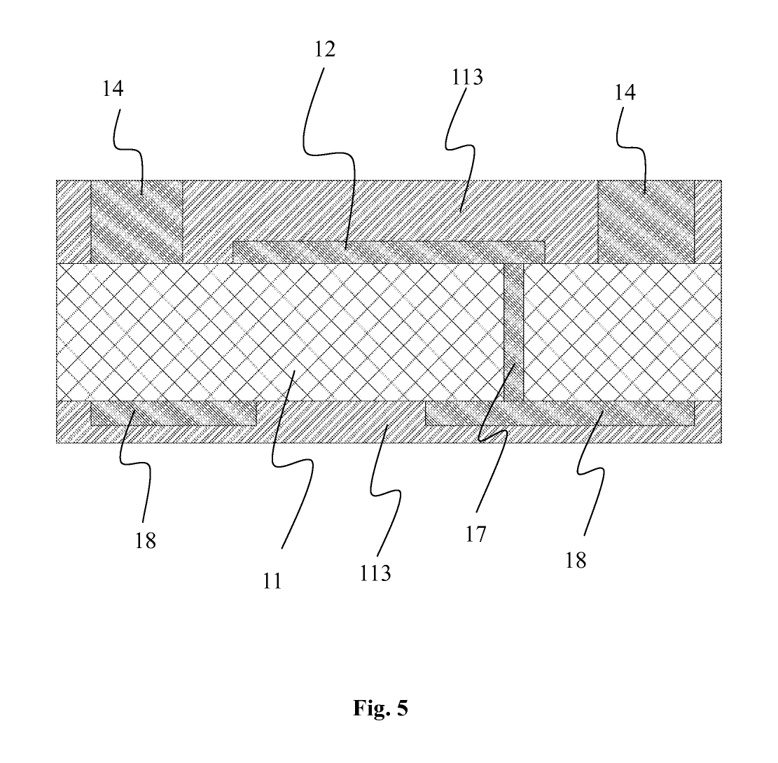

With reference to FIG. 4, this illustrates a cross section of the package structure of the present invention in the manufacturing process after FIG. 3. As shown, photo-resistors 113 are patterned on the first surface and the second surface of the substrate 11, the redistribution layer 18 and the first conductive layer 12. Moreover, a slot 13 surrounded the first conductive layer 12 is formed on the first surface of the substrate 11 for defining the position of second conductive layer 14 (shown in FIG. 5).

With reference to FIG. 5, this illustrates a cross section of the package structure of the present invention in the manufacturing process after FIG. 4. As shown, a second conductive layer 14 is plated in one piece on the first surface of the substrate 11 within the slot by DPC. Moreover, the height of the second conductive layer 14 is higher than the first conductive layer 12.

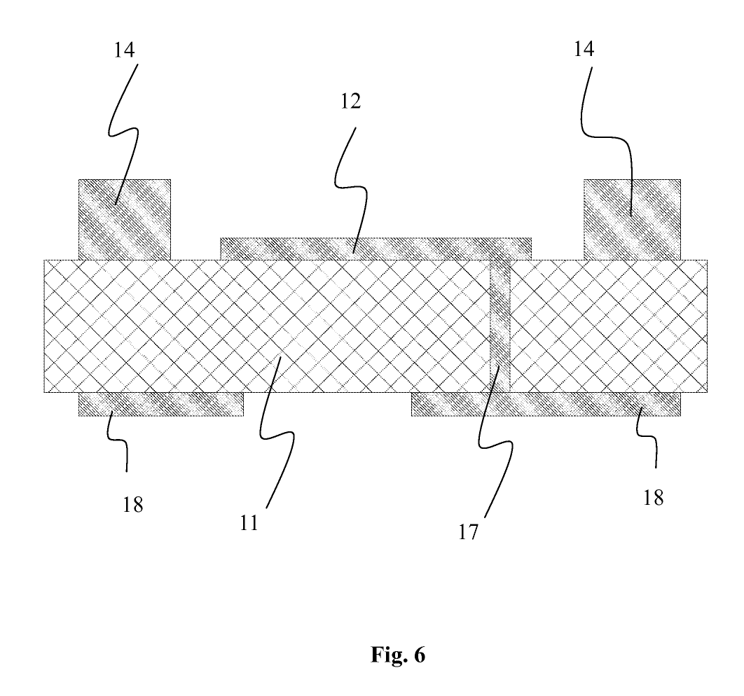

With reference to FIG. 6, this illustrates a cross section of the package structure of the present invention in the manufacturing process after FIG. 5. As shown, after the second conductive layer 14 is formed, the photo-resistors 113 are stripped by etching.

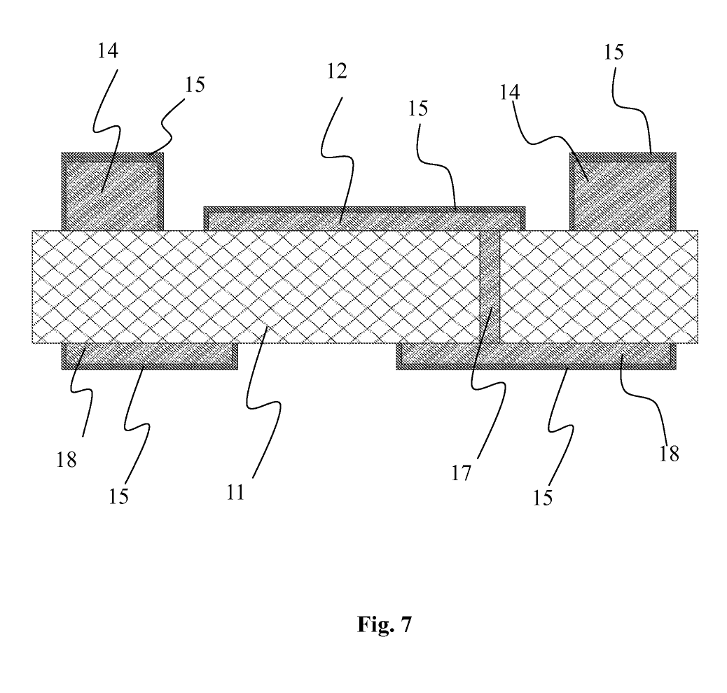

With reference to FIG. 7, this illustrates a cross section of the package structure of the present invention in the manufacturing process after FIG. 6. As shown, a surface finish layer 15 is formed on the surfaces of the first conductive layer 12 [symbol] the second conductive layer 14 and the redistribution layer 18 for protecting the first conductive layer 12 [symbol] the second conductive layer 14 and the redistribution layer 18. The surface finish layer 15 is formed on the surfaces of the first conductive layer 12 and the second conductive layer 14 and the redistribution layer 18 by electrochemical deposition. Moreover, the surface finish layer 15 is consisted of gold and nickel.

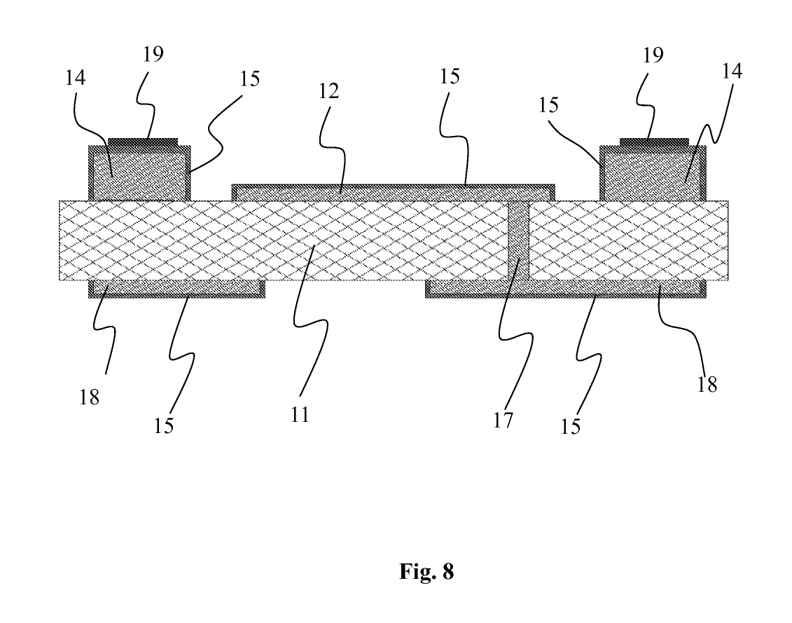

With reference to FIG. 8, this illustrates a cross section of the package structure of the present invention in the manufacturing process after FIG. 7. As shown, an adhesive layer 19 is plating on the top of the second conductive layer 14. The adhesive layer 19, for example but not limited, is a metal adhesive, such as AuSn alloy.

With reference to FIG. 9, this illustrates a cross section of the package structure of the present invention in the manufacturing process after FIG. 8. As shown, a semiconductor element 20 electrically connects to the first conductive layer 12 on the first surface of the substrate 11 and the metal contact 17. The semiconductor element 20 and the first conductive layer 12 are electrically connected by bumps of flip chip bonding, wherein the bump is comprised of conductive material, such as solder. Then, a lid 16 is attached to the top of the second conductive layer 14 by the adhesive layer 19 (shown in FIG. 6). Due to the height of the second conductive layer 14 is higher than the first conductive layer 12, the semiconductor element 20 is, therefore, sealed. Moreover, the lid 16 is formed by ceramic materials.

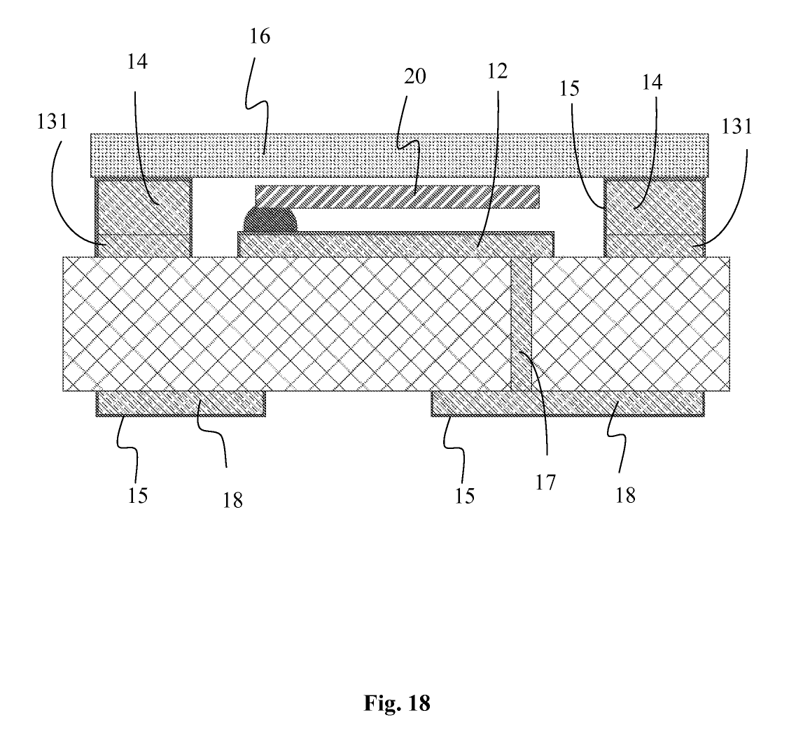

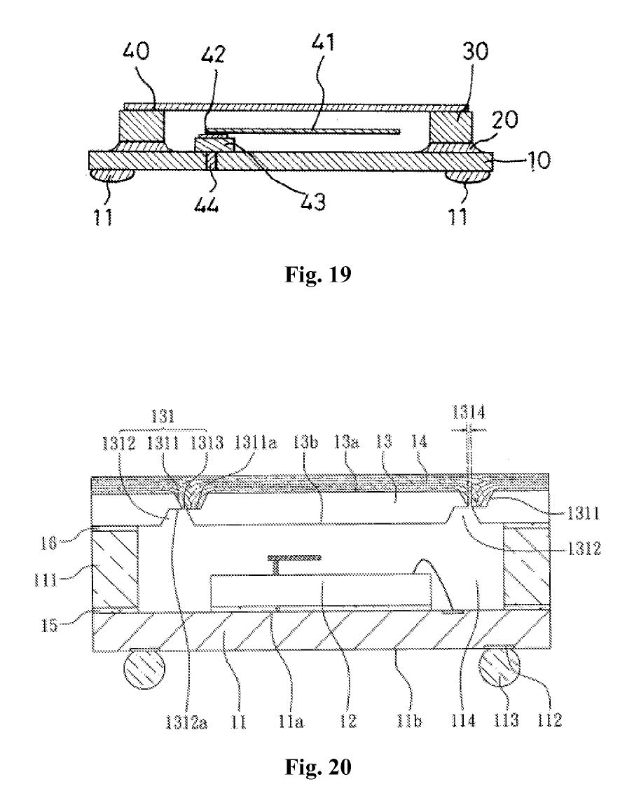

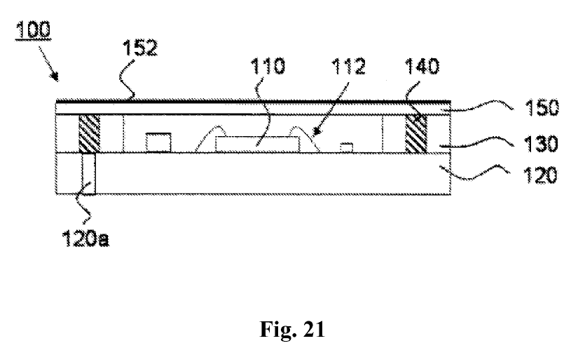

With reference to FIG. 18, a cross section view of the semiconductor package structure of the present invention is illustrated. The semiconductor package structure 10 comprises a substrate 11 having a first surface and a second surface, a first conductive layer 12, a second conductive layer 14, a third conductive layer 131, a surface finish layer 15, a semiconductor element 20 and a lid 16. The substrate 11 is a ceramic substrate. The first conductive layer 12 and the third conductive layer 131 are both plated on the first surface of the substrate 11, wherein the third conductive layer 131 surrounds the first conductive layer 12, and the semiconductor element 20 attaches to the first conductive layer 12 on the first surface of the substrate 11 to electrically connect the first conductive layer 12 and the metal contact 17. The second conductive layer 14 is plated on the third conductive layer 131 and surrounds the semiconductor element 20 and the first conductive layer 12. The surface finish layer 15 is formed on the surfaces of the first conductive layer 12 and second conductive layer 14 for protecting the first conductive layer 12 and second conductive layer 14. The lid 16 is attached to the top of the second conductive layer 14 for sealing the semiconductor element 20.

With reference to FIG. 18, the substrate 11 further comprises a metal contact 17 extending from the first surface to the second surface for electrically connecting to the first conductive layer 12. The lid 16 is formed by metal. The semiconductor element 20 and the first conductive layer are electrically connected by flip chip bonding. Moreover, the semiconductor package structure 10 further comprises a redistribution layer 18 plated on the second surface of the substrate 11 for electrically connecting to the metal contact 17, wherein the redistribution layer 18 is plated by the surface finish layer 15. Therefore, the semiconductor element 20 is electrically conducting to peripheral circuits through the first conductive layer 12, the metal contact 17 and the redistribution layer 18. The surface finish layer 15 formed on the surfaces of the first conductive layer 12, the second conductive layer 14 and the redistribution layer 18 by electrochemical deposition for protecting from rust is comprised of silver and nickel.

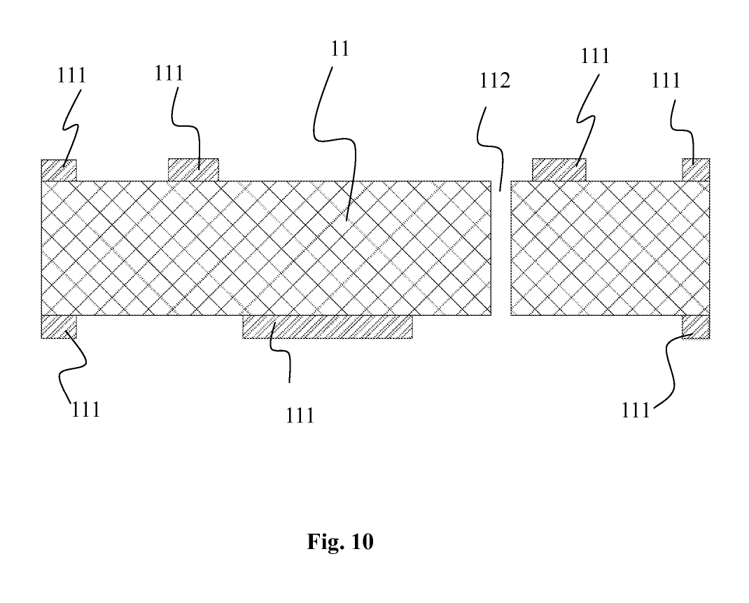

With reference to FIGS. 10 to 18, the semiconductor package structure of the present invention in the second manufacturing process is illustrated. As shown, a substrate 11 having a first surface and a second surface is provided at first. An opening 112 extending from the first surface and the second surface of the substrate 11 is formed by laser drilling. With plating conductive layers on particular position of the substrate 11, photo-resistors 111 should be patterned on the first surface and the second surface of the substrate 11 for defining the conductive layers plating position. Moreover, the substrate 11 is a ceramic substrate.

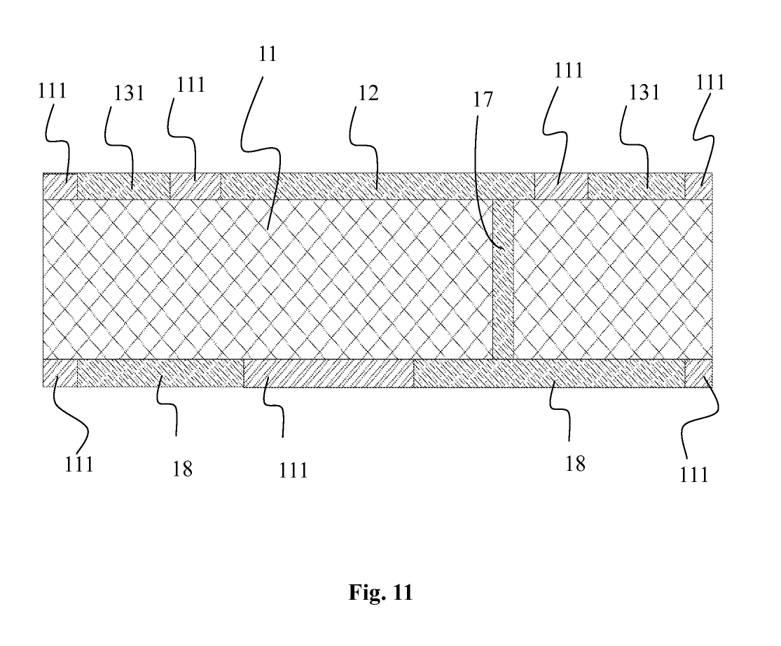

With reference to FIG. 11, this illustrates a cross section of the package structure of the present invention in the manufacturing process after FIG. 10. As shown, a metal contact 17 is formed in the opening extending from the first surface and the second surface of the substrate 1. A redistribution layer 18 is plated on the second surface of the substrate 11 by DPC. A first conductive layer 12 and a third conductive layer 131 is simultaneously plating on the first surface of the substrate 11 by DPC. Besides, the first conductive layer 12, the metal contact 17 and the redistribution layer 18 are electrically connected.

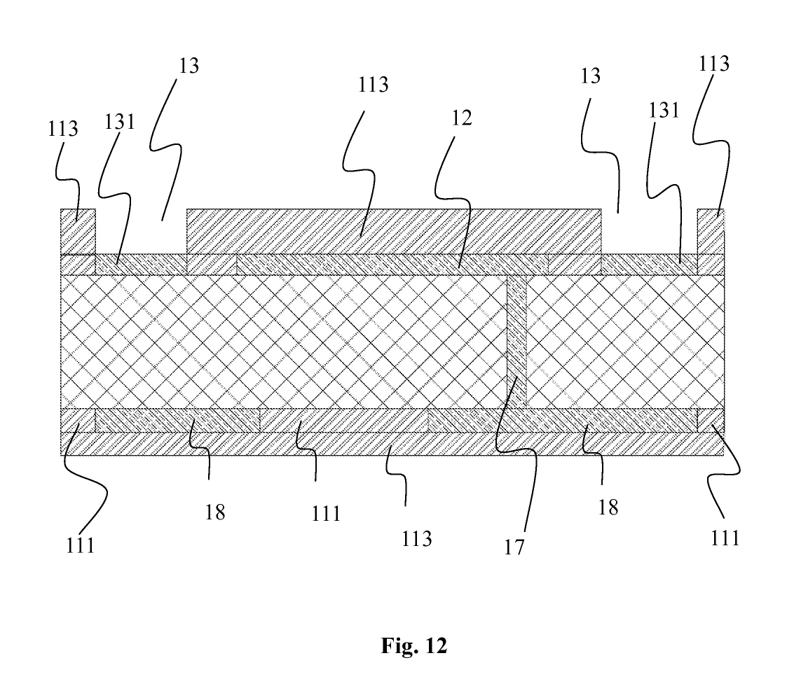

With reference to FIG. 12, this illustrates a cross section of the package structure of the present invention in the manufacturing process after FIG. 11. As shown, photo-resistors 113 are patterned on the first surface and the second surface of the substrate 11, the redistribution layer 18 and the first conductive layer 12. Moreover, a slot 13 surrounded the first conductive layer 12 is formed on the third conductive layer 131 for defining the position of conductive layer 14.

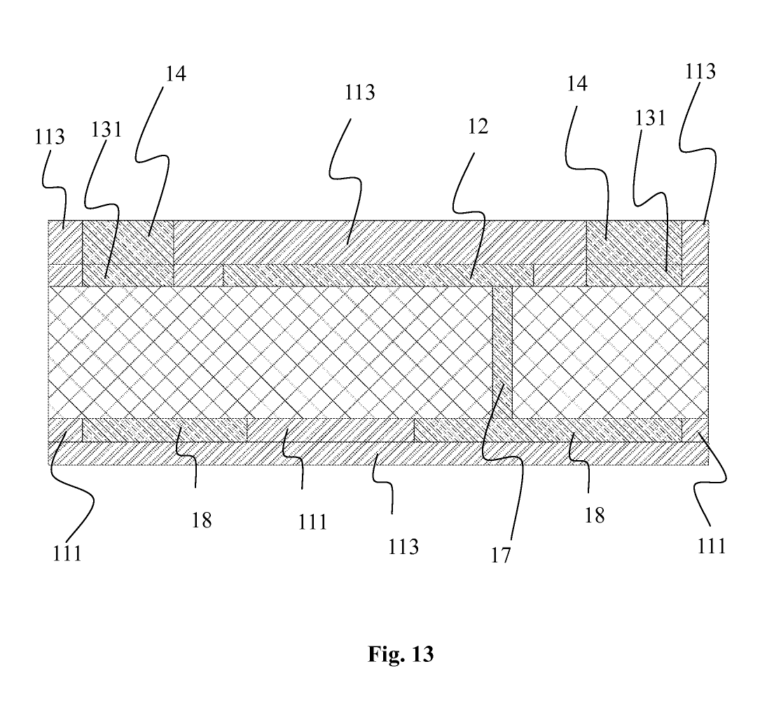

With reference to FIG. 13, this illustrates a cross section of the package structure of the present invention in the manufacturing process after FIG. 12. As shown, a second conductive layer 14 is plated on the third conductive layer 131 within the slot 13 by DPC. Moreover, the height of the second conductive layer 14 is higher than the first conductive layer 12.

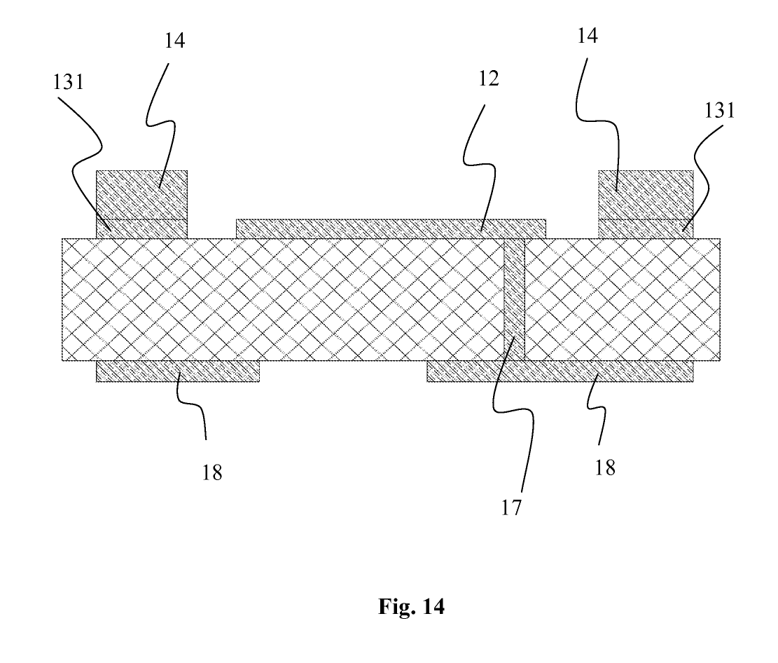

With reference to FIG. 14, this illustrates a cross section of the package structure of the present invention in the manufacturing process after FIG. 13. As shown, after the second conductive layer 14 is formed, the photo-resistors 113 are stripped by etching.

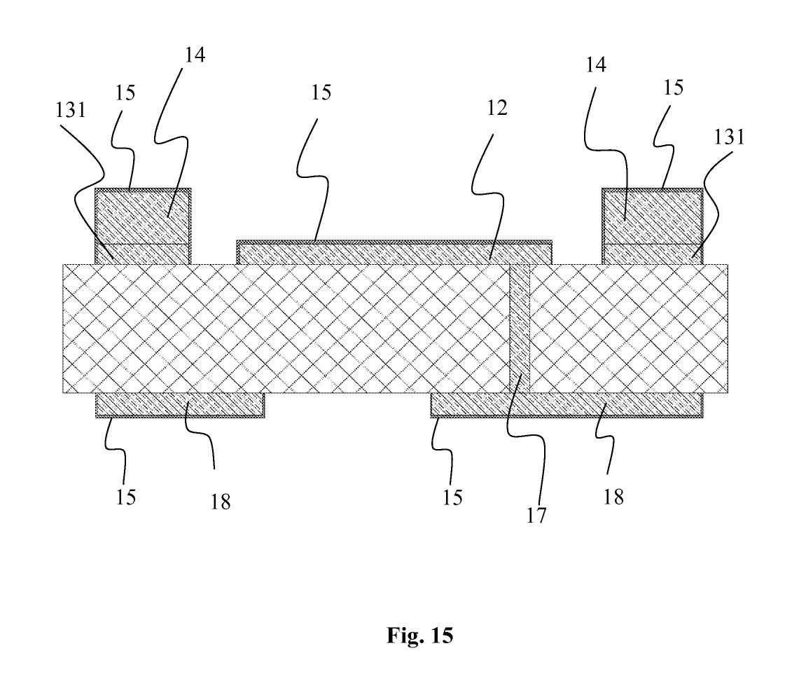

With reference to FIG. 15, this illustrates a cross section of the package structure of the present invention in the manufacturing process after FIG. 14. As shown, a surface finish layer 15 is formed on the surfaces of the first conductive layer 12, third conductive layer 131 and the second conductive layer 14 and the redistribution layer 18 for protecting the first conductive layer 12, third conductive layer 131 and the second conductive layer 14 and the redistribution layer 18. Moreover, the surface finish layer 15 is comprised of silver and nickel. The surface finish layer 15 is formed on the surfaces of the first conductive layer 12, third conductive layer 131, the second conductive layer 14 and the redistribution layer 18 by electrochemical deposition.

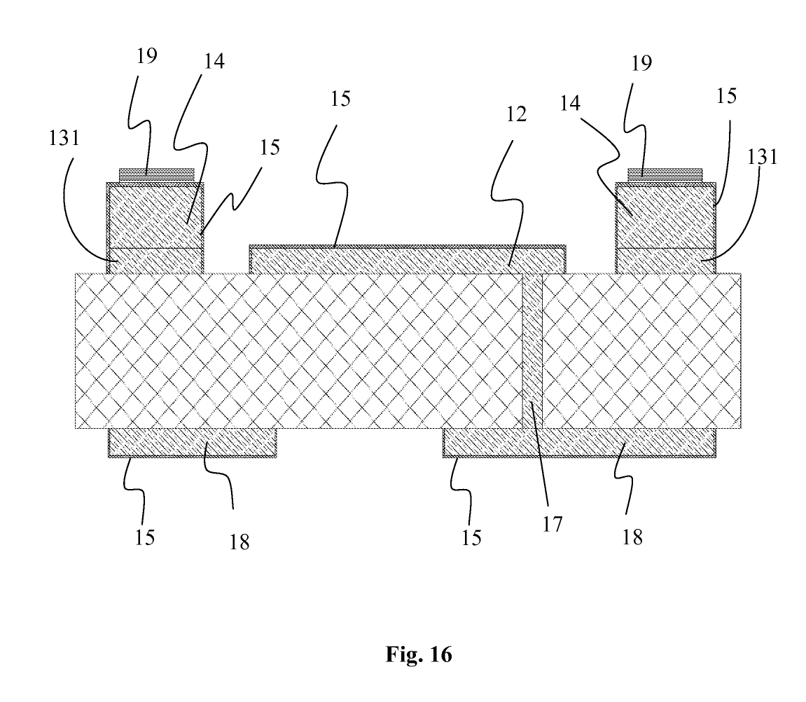

With reference to FIG. 16, this illustrates a cross section of the package structure of the present invention in the manufacturing process after FIG. 15. As shown, an adhesive layer 19 is plated on the top of the second conductive layer 14. The adhesive layer 19, for example but not limited, is a metal adhesive, such as AuSn alloy.

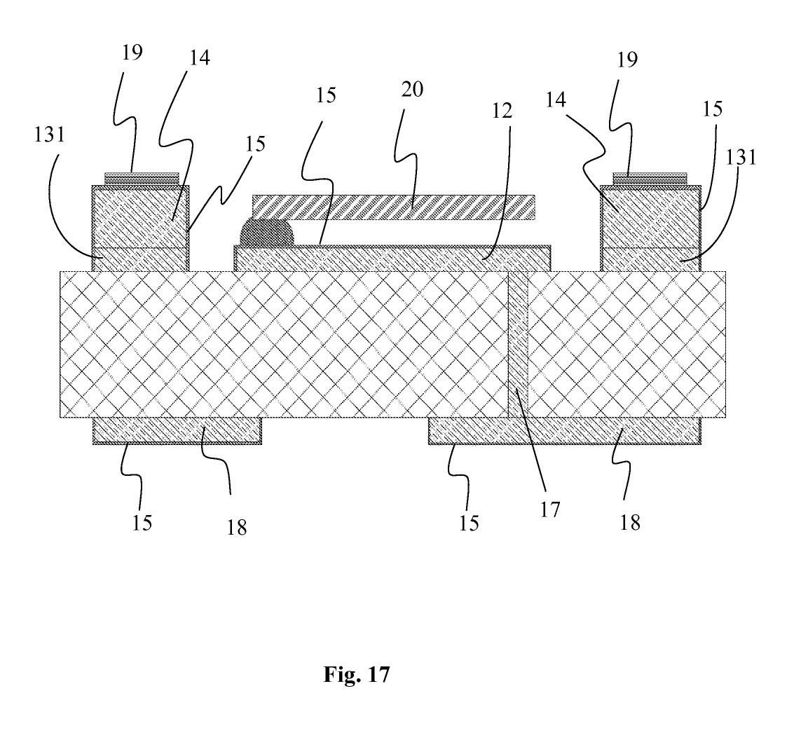

With reference to FIG. 17, this illustrates a cross section of the package structure of the present invention in the manufacturing process after FIG. 16. As shown, the semiconductor element 20 attaches to the first conductive layer on the first surface of the substrate 11 to electrically connect the first conductive layer 12 and the metal contact 17. The semiconductor element 20 and the first conductive layer 12 are electrically connected by flip chip bonding, wherein the material of the wire is comprised of conductive material, such as gold.

With reference to FIG. 18, this illustrates a cross section of the package structure of the present invention in the manufacturing process after FIG. 17. A lid 16 is attached to the top of the second conductive layer 14 by the adhesive layer 19 (shown in FIG. 16), wherein the lid 16 is formed by metal. Due to the height of the second conductive layer 14 is higher than the first conductive layer 12, the semiconductor element 20 is, therefore, sealed. Moreover, the lid 16 is formed by metal or ceramic materials.

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. A semiconductor package structure, comprising:
a substrate having a first surface, a second surface and a metal contact penetrating the substrate from the first surface to the second surface;
a first conductive layer which is plated on the first surface of the substrate and connected to the metal contact;
a semiconductor element electrically connecting the first conductive layer on the first surface of the substrate;
a second conductive layer which is plated on the first surface of the substrate surrounding the first conductive layer and the semiconductor element, wherein the height of the second conductive layer is higher than the height of the first conductive layer; and
a lid attached to the top of the second conductive layer for sealing the semiconductor element.

2. The semiconductor package structure according to claim 1, wherein the substrate is a ceramic substrate.

3. The semiconductor package structure according to claim 1, further comprising a third conductive layer between the first surface of the substrate and the second conductive layer, wherein the third conductive layer surrounds the first conductive layer.

4. The semiconductor package structure according to claim 1, further comprising a surface finish layer plated on the surface of the first and second conductive layer.

5. The semiconductor package structure according to claim 3, further comprising a surface finish layer plated on the surface of the first conductive layer and second conductive layer and third conductive layer.

6. The semiconductor package structure according to claim 1, wherein the lid is formed by a material selected from a group consisting of metal, alloy, metal composite, plastic, and ceramic materials.

7. The semiconductor package structure according to claim 1, wherein the semiconductor element and the first conductive layer are electrically connected by wires, wherein the wires are comprised of conductive materials.

8. The semiconductor package structure according to claim 1, wherein the semiconductor element and the first conductive layer are electrically connected by bumps, wherein the bumps are comprised of conductive materials.

9. The semiconductor package structure according to claim 4, further comprising a redistribution layer plated on the second surface of the substrate and electrically connecting to the metal contact, wherein the redistribution layer is plated by the surface finish layer.

10. The semiconductor package structure according to claim 5, further comprising a redistribution layer plated on the second surface of the substrate and electrically connecting to the metal contact, wherein the redistribution layer is plated by the surface finish layer.

11. The semiconductor package structure according to claim 4, wherein the surface finish layer is selected from a group consisting of Ag, Au, Ni, Pd, and a combination of those.

12. The semiconductor package structure according to claim 5, wherein the surface finish layer is selected from a group consisting of Ag, Au, Ni, Pd, and a combination of those.

13. The semiconductor package structure according to claim 9, wherein the surface finish layer is selected from a group consisting of Ag, Au, Ni, Pd, and a combination of those.

14. The semiconductor package structure according to claim 10, wherein the surface finish layer is selected from a group consisting of Ag, Au, Ni, Pd, and a combination of those.

15. The semiconductor package structure according to claim 2, wherein the ceramic substrate is a multi-layer ceramic.

16. A method for manufacturing semiconductor package structure, comprising the steps of:
(a) providing a substrate having a first surface, a second surface and an opening penetrating the substrate from the first surface to the second surface;
(b) forming a metal contact in the opening;
(c) plating a first conductive layer on the first surface of the substrate, wherein the first conductive layer electrically connects to the metal contact;
(d) plating a second conductive layer on the first surface of the substrate for surrounding the semiconductor element and the first conductive layer, wherein the height of the second conductive layer is higher than the first conductive layer;
(e) attaching a semiconductor element to the first conductive layer on the first surface of the substrate for electrically connecting; and
(f) attaching a lid to the top of the second conductive layer for sealing the semiconductor element.

17. The method for manufacturing semiconductor package structure according to claim 16, wherein the substrate is a ceramic substrate.

18. The method for manufacturing semiconductor package structure according to claim 16, between the step (d) and (e), further comprising a step of plating a surface finish layer on the surfaces of the first and second conductive layer, wherein the surface finish layer is selected from a group consisting of Ag, Au, Ni, Pd, and a combination thereof.

19. The method for manufacturing semiconductor package structure according to claim 18, wherein the surface finish layer is formed by electrochemical deposition.

20. The method for manufacturing semiconductor package structure according to claim 16, wherein the lid is formed by a material selected from a group consisting of metal, alloy, metal composite, plastic, and ceramic materials.

21. The method for manufacturing semiconductor package structure according to claim 16, wherein the semiconductor element electrically connects to the first conductive layer by wire bonding.

22. The method for manufacturing semiconductor package structure according to claim 16, wherein the semiconductor element electrically connects to the first conductive layer by flip chip bonding.

23. The method for manufacturing semiconductor package structure according to claim 16, wherein the step (c) further comprises a step of plating a third conductive layer between the first surface of the substrate and the second conductive layer, the third conductive layer surrounding the semiconductor element and the first conductive layer

24. The method for manufacturing semiconductor package structure according to claim 16, after the step (b), further comprising a step of plating a redistribution layer on the second surface of the substrate for electrically connecting to the metal contact.

25. The method for manufacturing semiconductor package structure according to claim 23, further comprising a step of plating a redistribution layer on the second surface of the substrate for electrically connecting to the metal contact.

26. The method for manufacturing semiconductor package structure according to claim 16, wherein the step (b) and the step (c) take place simultaneously.
